(19) United States
(12) Patent Application Publication
(10) Pub. No.: US 2008/0265936 A1
(43) Pub. Date: Oct. 30, 2008

(54) Integrated circuit switching device, structure and method of manufacture

(75) Inventor: Madhu P. Vora, Los Gatos, CA (US)

Correspondence Address: HAVERSTOCK & OWENS, LLP, 162 North Wolfe Road, Sunnyvale, CA, 94086, US

(73) Assignee: DSM Solutions, Inc.

(21) Appl. No.: 11/796,434

(22) Filed: Apr. 27, 2007

(51) Int. Cl. H03K 19/177; H01L 21/82; H03K 17/687

(52) U.S. Cl. 326/41; 327/430; 438/128; 257/E21.602

(57) ABSTRACT

An integrated circuit device can include a plurality of field effect transistors (FETs) having channel depths no greater than a first depth, and at least a first switch junction FET (JFET) having a source coupled to a signal transmission input node, a drain coupled to a signal transmission output node, and a gate. The first switch JFET has a channel depth greater than the first depth. Switch JFETs can enable low resistance configurable switch paths to be created for interconnecting different portions of a same integrated circuit device.

### TECHNICAL FIELD

The present invention relates generally to semiconductor integrated circuit devices, and more particularly to switching devices within integrated circuit devices that can selectively enable signal transmission across, to or from an integrated circuit device.

### BACKGROUND OF THE INVENTION

Integrated circuit (IC) devices can include a number of sections formed in one or more substrates that are electrically interconnected to one another. In order to provide increased operating speeds, it is desirable to provide as fast a signal transmission speed as possible for signal paths that interconnect different sections. For some integrated circuit devices, critical timing paths can be identified prior to the fabrication of the device, and thus optimized (e.g., utilize large signal driving devices, minimize routing lengths, increase signal line cross sectional size to reduce resistance).

However, for other integrated circuit devices signal paths can be configured after the device has been manufactured, by connecting different signal paths with switches. In such cases, complete signal routing paths are unknown at the time of fabrication and thus cannot be optimized in the manner described above. Further, because configuration of signal paths can depend upon a series of switches, signal switch construction can limit overall performance of the devices. For example, programmable logic devices (PLDS) can often include signal paths configurable by enabling (placing into a relatively low impedance state) or disabling (placing into a relatively high impedance state) various switching devices. Programmable logic devices can include, as but a few examples, complex PLDs (CPLDs) and programmable gate arrays (PGAs) including field PGAs (FPGAs).

To better understand various features of the disclosed embodiments, a conventional switching arrangement for an FPGA will now be described.

Referring now to FIG. 12A, a conventional FPGA is shown a block diagram and designated by the general reference character 1200. An FPGA 1200 can include a number of logic blocks (two shown as 1202-0 and 1202-1) interconnected by a configurable wiring. A configurable wiring can include wiring sets (one shown as 1204) that can be interconnected with adjacent wiring sets by switching circuits (one shown as 1206). Switching circuits include switch devices that can electrically connect or isolate one wiring line from one or more other wiring lines.

Depending upon the desired logic function of a FPGA, signal paths between logic blocks can be enabled or disabled. For example, FIG. 12A shows one possible signal path 1208 as a bold line, that interconnects logic block 1202-0 with logic block 1202-1. As shown, this signal path passes through 10 switch circuits.

Referring now to FIG. 12B, a conventional switch device 1210 that can be included in switching circuits (e.g. 1206) is shown in a schematic diagram. A switching circuit can include a metal-oxide-semiconductor (MOS) transistor having a source-drain path connected between one wiring line and another, as well as a gate that receives a configuration value CFG. Switch device 1210 can be enabled or disabled according to value CFG.

Referring now to FIG. 12C, an equivalent model for a MOS switch device 1210 is shown in a schematic diagram and designated by the reference character 1220. A model 1220 can include a series resistance Req and a parallel capacitance Ceq. In a MOS transistor based switch device, like that of FIG. 12B, Req can typically be about 5000 ohms, for a device having a channel width of about 1 μm and a channel length of about 65 nm.

FIG. 12D shows an equivalent circuit for a switching path like that shown as 1208 in FIG. 12A. As shown, each switching circuit (SW1 to SWn) can introduce its own resistance and capacitance.

FIG. 12E shows the effect of resistance and capacitance introduced into a signal path by conventional switching circuits. FIG. 12E is a timing diagram showing a signal Sin applied at an input to a signal path (e.g., output from logic block 1202-0) and a resulting signal Sout provided at an output of the signal path (e.g., input to logic block 1202-1). As shown, signal delay and skew can result. As understood from FIG. 12A, a signal path 1208 shown in FIG. 12A can have a total resistance in the order of 50 kohms. Combined with the capacitance of each switch, a signal path can introduce a delay ranging from 10 to 100 nS. This can limit a clock rate of a conventional FPGA to about 5° Mhz.

### BRIEF SUMMARY OF THE INVENTION

An integrated circuit device can include a number of field effect transistors (FETs) having channel depths no greater than a first depth. The integrated circuit device can also include one or more switch junction FETs (JFETs). A first switch JFET can have a source coupled to a signal transmission input node, a drain coupled to a signal transmission output node, and a gate. The first switch JFET has a channel depth greater than the first depth.

A method of fabricating an integrated circuit device can include the steps of: forming a first active area for at least one shallow channel FET having impurities extending into a first substrate region to a depth d; forming a second active area for at least one deep channel JFET having impurities extending into a second substrate region to a depth greater than d; and forming at least a gate terminal of the at least one deep channel JFET by patterning an electrode semiconductor material formed on, and in contact with, at least a portion of the second substrate region.

An integrated circuit design can include logic circuit structures defined as operating within a first voltage range. Each section can be defined as including enhancement mode FETs. The design can include one or more switching structures defined as connecting one signal node to another signal node. A switching structure can include one or more depletion mode JFETs. Such a depletion mode JFET can receive a configuration signal at its gate having a swing greater than the first voltage range.

An integrated circuit device can include one or more logic blocks, each configurable to execute one of multiple logic functions. Each logic block can include multiple transistors and a number of switch circuits. Each switch circuit can have at least one switch path configurable to electrically interconnect one or more logic blocks with one another. Each switch path can include one or more depletion mode switch JFETs.

### BRIEF DESCRIPTION OF THE DRAWINGS

FIG. 1 is a block schematic diagram of an integrated circuit device according to a first embodiment.

FIGS. 2A to 2C shows examples of shallow channel field effect transistors (FETs) that can be included in embodiments of the invention.

FIGS. 3A-0 to 3D show examples of deep channel junction FETs (JFETs) that can be included in embodiments of the invention.

FIG. 4 is a block schematic diagram of a switch structure according to an embodiment of the invention.

FIG. 5 is a block schematic diagram of a switch structure according to another embodiment of the invention.

FIG. 6 is a block schematic diagram of a switch structure according to yet another embodiment of the invention.

FIGS. 7A to 7C show programmable switch sections according to various embodiments of the invention.

FIGS. 8A and 8B show portions of a programmable logic device according to embodiments of the present invention.

FIG. 8C show a field programmable gate array (FPGA) device according to an embodiment of the invention.

FIGS. 9A to 9G are a series of side cross sectional views illustrating a method of fabricating shallow and deep channel JFETs in a same substrate.

FIGS. 10A to 10L are a series of side cross sectional views illustrating a method of fabricating shallow channel insulated gate FETs and deep channel JFETs in a same substrate.

FIG. 11 is a diagram showing an integrated circuit design according to an embodiment.

FIG. 12A shows a signal path for a conventional FPGA.

FIG. 12B shows a conventional switching device for an FPGA.

FIG. 12C shows an equivalent model for the switching device of FIG. 12B.

FIG. 12D shows an equivalent circuit for a signal path like that shown in FIG. 12A.

FIG. 12E is a timing diagram showing the effect of conventional switching devices on signal propagation.

### DETAILED DESCRIPTION OF THE EMBODIMENTS

Various embodiments of the present invention will now be described in detail with reference to a number of drawings. The embodiments show structures, designs, and methods for an integrated circuit (IC) device that can provide lower resistance switching devices than conventional approaches, like those that include metal-oxide-semiconductor type transistors as switching devices.

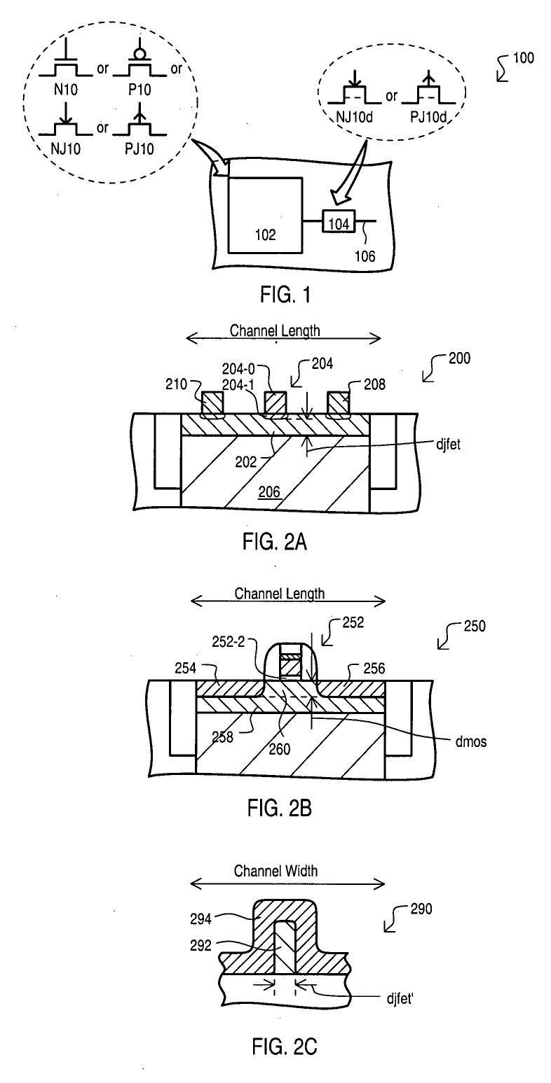

Referring now to FIG. 1, an IC according to a first embodiment is shown in a top plane view, and designated by the general reference character 100. An IC 100 can include a first section 102 and a switch section 104. Switch section 104 can provide a switchable path between first section 102 and a node 106. A first section 102 can include circuits formed by “shallow” channel transistors. Such shallow channel transistors can include n-channel insulated gate field effect transistors (IGFETs) (one shown as N10) and/or p-channel IGFETs (one shown as P10). In addition or alternatively, such shallow channel transistors can include n-channel junction field effect transistors (JFETs) (one shown as NJ10) and/or p-channel JFETs (one shown as PJ10). Preferably, shallow channel transistors can be enhancement mode transistors.

A switchable path of a switch section 104 can be formed in whole, or in part, by a “deep” channel JFET. A deep channel JFET can be a deep n-channel JFET (one shown as NJ10d) and/or a deep p-channel JFET (one shown as PJ10d). A deep channel JFET can provide a lower resistance proportional to channel width when a channel is in a conducting state, than a shallow channel FET like that in first section 102. A deep channel JFET can be a depletion mode transistor.

In this way, an integrated circuit can include a low resistance, deep channel JFET device in switching paths for signals.

Prior to describing possible deep channel JFET structures, possible shallow channel FET structures that can be included with deep channel JFETs will first be described.

Referring now to FIG. 2A, one example of a shallow channel device is shown in a cross sectional view taken along the transistor length direction, and designated by the general reference character 200. A shallow channel device 200 can be a JFET having a channel region 202 doped to a first conductivity type (e.g., n or p), and a gate structure 204 and well (or back gate structure) 206 both doped to a second conductivity type (e.g., p or n). Preferably, a channel region 202 can have a doping concentration based on an ion implantation dose in the range of 10¹⁸/cm². A gate structure 204 can include a gate electrode 204-0 and a gate portion 204-1 that extends into the channel region 202. Preferably, a JFET can be an enhancement mode device. That is, due to the size and doping of the device, built-in depletion regions can maintain a channel region 202 in a relatively high impedance state absent a gate voltage. In one particular arrangement, shallow channel JFETs can have a threshold voltage with an absolute value in the range of about 0.7 volts, preferably no more than about 0.5 volts. A resulting channel resistance (when the channel is in a conductive state) for a shallow channel JFET 200 having a channel width of about 1 μm, and a channel length of about 65 nm can be about 5 kohms.

The conductivity of a channel region 202 can be controlled according to potentials applied to gate structure 204, back gate structure 206, or both.

A shallow channel JFET 200 can also include source/drain terminals 208/210. Source/drain terminals 208/210 can be doped to the same conductivity type as channel region 202. In one particular arrangement, a gate electrode 204-0 and source/drain terminals 208/210 can be formed from a same semiconductor material deposited on a substrate containing channel region 202. Thereafter, source/drain regions can be formed that extend into channel region 202 below corresponding source/drain terminals 208/210.

A shallow channel JFET 200 can have a channel region 202 with a depth “djfet” that extends between gate electrode 204 and back gate structure 206. In one particular arrangement, a depth “djfet” can be about 200 angstroms.

FIG. 2B shows another example of a shallow transistor that can be included in an integrated circuit that also includes a deep channel JFET device. FIG. 2B shows an insulated gate field effect transistor (IGFET), taken along the length direction, designated by the general reference character 250. An IGFET 250 can be conventional in construction, including an insulated gate electrode 252 and source/drain regions 254/256. Gate electrode 252 can include a gate insulating layer 252-2 that electrically isolates conductive portions of the gate electrode 252 from a channel region 260. Source/drain regions 254/256 can be formed in a body region 258. Preferably, an IGFET 250 can be an enhancement mode device, and can create a channel 260 between source/drain regions 254/256 by application of a voltage to gate electrode 252. Shallow channel IGFETs can have threshold voltages in the general range of about 0.7 volts. A resulting channel “on” resistance for a shallow channel IGFET 250 having a channel width of about 1 μm, and a channel length of about 65 nm can also be about 5 kohms.

A shallow channel IGFET 250 can form or include a channel region 260 with a depth “dmos” that extends below gate electrode 252.

FIG. 2C shows a third example of a possible shallow channel device. FIG. 2C shows a JFET having some of the same structures as that of FIG. 2A, accordingly, like sections are referred to by the same reference character but with the first two digits being “29” instead of “20”. FIG. 2C shows a JFET 290 in cross section taken along a width direction through a gate structure 294.

FIG. 2C shows an example of a channel region 292 having a “fin” like structure with a gate structure 294 on opposing sides of channel 292. As in the case of FIG. 2A, JFET 290 can be preferably be an enhancement mode device.

Shallow channel JFET 290 can have a channel region 292 with a depth “djfet′” that extends across channel region 292.

Having described examples of shallow channel transistors, various examples of possible deep channel JFETs will now be described.

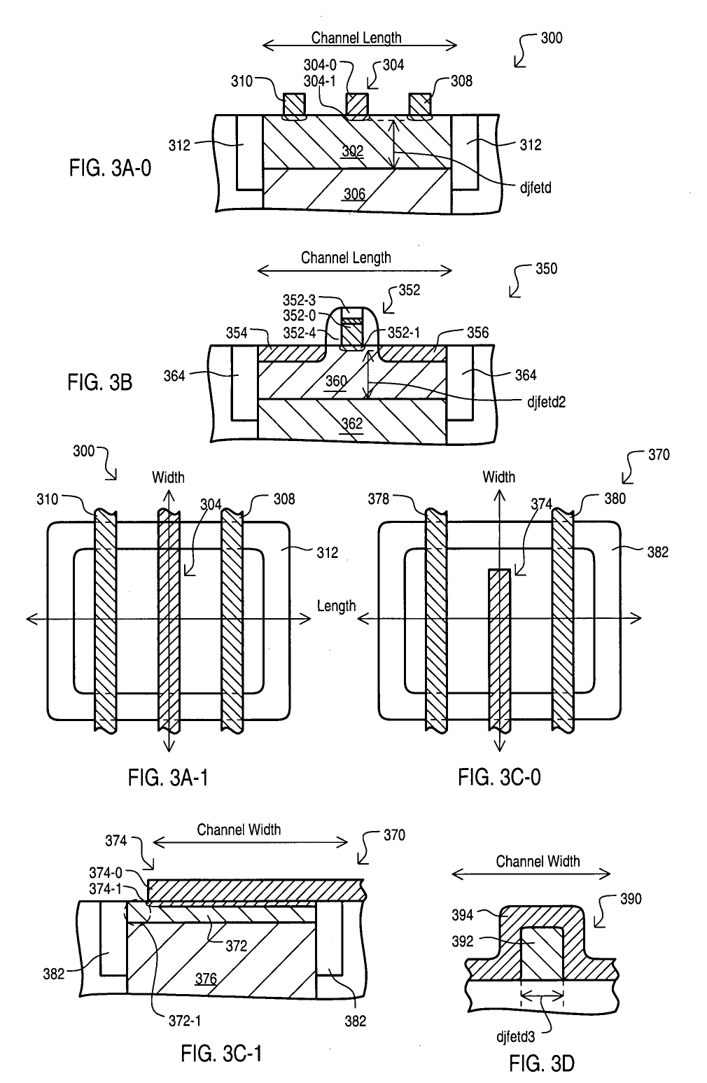

A first example of a deep channel JFET is shown in FIGS. 3A-0 and 3A-1. FIG. 3A-0 shows a deep channel JFET in a cross sectional view taken along the transistor length direction, and designated by the general reference character 300. FIG. 3A-1 shows the same deep channel JFET 300 in a top plan view. Deep channel JFET 300 can include the same general components as shallow channel JFET 200 shown in FIG. 2A, accordingly, like sections are referred to by the same reference character but with the first digit being “3” instead of “2”.

A deep channel JFET 300 can include a channel region 302 that can be surrounded by an insulating structure 312. In one particular example, an insulating structure 312 can be shallow trench isolation (STI) structures.

Unlike the arrangement of FIG. 2A, deep channel JFET 300 can include a channel region 302 that can extend deeper into a substrate than that of the shallow channel counterpart shown in FIG. 2A. Preferably, a deep channel region 302 can be doped to a lower dopant concentration than a channel region of a shallow channel JFET (e.g., 202 in FIG. 2A). As but one example, if a shallow channel 202 is formed with an ion implantation dose of about 10¹⁸/cm², a deep channel region 302 can have a doping concentration based on an ion implantation dose in the range of 10¹⁷/cm². A deep channel region 302 can have suitably higher implantation energies to achieve a desired channel depth.

A deep channel JFET 300 can operate as a depletion mode device. Consequently, a deep channel JFET 300 can have a pinch off voltage significantly higher than a threshold voltage of a shallow channel JFET, like that of FIG. 2A. As but one example, a deep channel p-type JFET can have a pinch off voltage in the range of about +1 to +5 volts. Similarly, a deep channel n-type JFET can have a pinch off voltage in the range of about −1 to −5 volts. A resulting channel on resistance for a deep channel JFET 300 having a channel width of about 1 μm, and a channel length of about 65 nm can be about 500 ohms. This can be an order of magnitude lower than a shallow channel JFET, like that shown in FIGS. 3A-0 and 3A-1, having the same width/length dimensions.

The conductivity of a channel region 302 can be controlled according to potentials applied to gate structure 304, back gate structure 306, or both.

Like shallow channel JFET 200, deep channel JFET 300 can also include source/drain terminals 308/310. Further, source/drain terminals 308/310 can be doped to the same conductivity type as channel region 302, and in one particular arrangement, a gate electrode 304-0 and source/drain terminals 308/310 can be formed from a same semiconductor material deposited on a substrate containing channel region 302. Thereafter, source/drain regions can be formed that extend into channel region 302 below corresponding source/drain terminals 308/310.

A deep channel JFET 300 can have a channel region 302 with a depth “djfetd” that extends between gate electrode 304 and back gate 306.

A deep channel JFET 300 can be advantageously compatible with manufacturing methods that also form shallow channel JFETs like that shown in FIG. 2A, as many structures are similar between the two device types.

While a deep channel JFET can have a structure the generally follows that of a shallow channel JFET shown in FIG. 2A, alternate embodiments can include deep channel JFETs having structures that are similar to those of IGFETs. One such example is shown in FIG. 3B.

FIG. 3B shows a deep channel JFET in a cross sectional view taken along the transistor length direction, and designated by the general reference character 350. Deep channel JFET 350 can include items similar to that of shallow channel IGFET 250 shown in FIG. 2B, accordingly, like sections are referred to by the same reference character but with the first digit being “3” instead of “2”.

Deep channel JFET 350 can include a channel region 360 that can be surrounded by an insulating structure 364. In one particular example, an insulating structure 364 can be a shallow trench isolation (STI) type structure.

Unlike the arrangement of FIG. 2B, deep channel JFET 350 can includes a channel region 360 that is not an inversion region produced by application of a gate voltage. Further, a channel region 360 can extend deeper than the inversion channel shown in FIG. 2B. Consequently, deep channel JFET 350 can be a depletion mode device, and can be pinched off in the same fashion as the structure shown in FIGS. 3A-0 and 3A-1. In addition, a deep channel JFET 350 can include a back gate structure 362 below channel region 360. As in the case FIGS. 3A-0 and 3A-1, a back gate structure 362 can be doped to a conductivity type opposite to that of channel region 360.

In addition, in the arrangement of FIG. 3B, a gate structure 352 does not include a gate insulating layer. Instead, a gate structure 352 can include a gate electrode 352-0 formed, at least in part, by a semiconductor material in contact with a channel region 360, but doped to an opposite conductivity type as channel region 360. In addition, a gate structure 352 may also include gate portion 352-1 extending into a substrate that is also doped to an opposite conductivity type as channel region 360.

Still further, a gate structure 352 can optionally include a top gate insulating layer 352-3 formed over gate electrode 352-0, as well as side wall insulators 3524 formed on side surfaces of gate electrode 352-0.

The conductivity of a channel region 360 can be controlled according to potentials applied to gate structure 352, back gate structure 362, or both.

The particular arrangement of FIG. 3B also shows source/drain regions 354/356 formed within channel region 360. Source/drain regions 354/356 can be doped to a same conductivity as channel region 360, but at a higher concentration.

A deep channel JFET 350 can include a channel region 360 with a depth “djfetd2” that extends between gate structure 352 and back gate structure 362.

A deep channel JFET 350 can be advantageously compatible with existing IGFET manufacturing methods that also form shallow channel JFETs like that shown in FIG. 2B, as many structures are similar between the two transistor structures.

While a deep channel JFET 350 can provide increased channel area by increasing channel size in a direction perpendicular to a substrate surface (i.e., a vertical direction in FIGS. 3A-0 and 3B), alternate embodiments can increase channel size in a direction parallel to a substrate surface. One such example is shown in FIGS. 3C-0 and 3C-1.

FIG. 3C-0 shows a top plan view of a deep channel JFET 370. FIG. 3C-1 shows a side cross sectional of deep channel JFET 370 taken along a transistor width direction (line “Width” in FIG. 3C-0). Deep channel JFET 370 can include the same general components as that of FIGS. 3A-0 and 3A-1, accordingly, like sections are referred to by the same reference character but with the first two digits being “37/38” instead of “30/31”.

Unlike the arrangement of FIGS. 3A-0 and 3A-1, deep channel JFET 370 can include a channel region 372 that is shallower than that shown in FIG. 3A-0. However, as shown in FIG. 3C-1, a channel region 372 can include a portion 372-1 not covered by a gate structure 374. This is in contrast to the arrangement shown by FIG. 3A-1, which a gate structure 304 crosses over all of a channel region in the width direction. As a result, a deep channel JFET 370 can operate as a depletion mode device and provide a lower resistance signal path.

In one arrangement, a side cross sectional view taken along line “Length” of FIG. 3C-0, could have the same general appearance as shallow channel JFET 200 shown in FIG. 2A.

The conductivity of a channel region 372 can be controlled according to gate structure 374, back gate structure 376, or both.

A deep channel JFET 370 can be advantageously compatible with manufacturing methods that also form shallow channel JFETs like that shown in FIG. 2A, as many structures are similar between the two transistor structures. In particular, channel depths may be the same between JFET 370 and JFET 200, unlike the arrangement of FIGS. 3A-0 and 3A-1.

Yet another example of a possible deep channel JFET is shown in FIG. 3D, in a cross sectional view taken along the transistor width direction, and designated by the general reference character 390. Deep channel JFET 390 can include the same general components as shallow channel JFET 290 shown in FIG. 2C, accordingly, like sections are referred to by the same reference character but with the first digit being “3” instead of “2”.

A deep channel JFET 390 can differ from the structure of FIG. 2C in that a channel region formed between gate structure 394 can be larger than that of FIG. 2C. As a result, deep channel JFET 390 can be a depletion mode device.

A deep channel JFET 390 can be advantageously compatible with manufacturing methods that also form shallow channel JFETs like that shown in FIG. 2C, as many structures are similar between the two transistor structures. For example, channel depth need only be extended in a lateral direction.

It is noted that an improvement (i.e., reduction) in channel resistance of a deep channel JFET, such as those shown in FIGS. 3A-0 to 3D, as compared to a shallow channel enhancement mode FETs, such as those shown in FIGS. 2A and 2C, can be achieved by increasing channel area, decreasing channel doping, or some combination thereof. For example, to achieve about a ten fold reduction in resistance, a channel of a deep channel JFET can be correspondingly (10×) greater in area. At the same time, if a channel doping is lowered (e.g., 10¹⁷/cm² from 10¹⁸ cm²), a channel size increase could be considerably less to achieve a same increase in conductivity (e.g., as little 2×).

In a preferred embodiment that includes shallow channel JFETs like those of FIG. 2A and deep channel JFETs like those of FIG. 3A-0, a deep channel JFET can have channel depth “djfetd” that is two to four times that of that of the shallow channel JFET depth “djfet”. Further, a deep channel JFET can have a channel dopant concentration that is 10× less than that of the shallow channel counterpart.

In this way, deep channel JFETs can be provided in an integrated circuit that includes shallow channel devices. Such deep channel JFETs can include structures that provide a lower “on” resistance than the shallow channel devices.

Having shown a general integrated circuit structure and corresponding device structures, more particular circuit structures according to various embodiments will now be described.

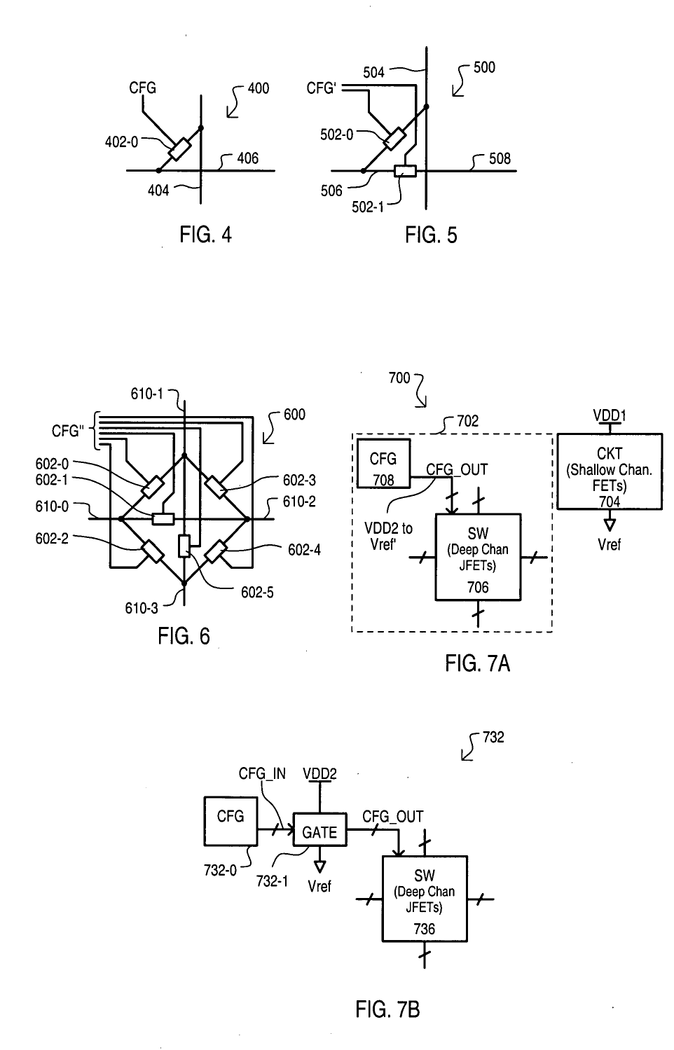

Referring now to FIG. 4, a switch structure according to one embodiment is shown in a block schematic diagram and designated by the general reference character 400. A switch structure 400 can be a “crossbar” type switch that includes a switch device 402-0, a first signal line 404 and a second signal line 406. A switch device 402-0 can include a deep channel JFET according to any of the above described embodiments or equivalents. Such a deep channel JFET can have a source-drain path connected between first signal line 404 and second signal line 406, and a control terminal (e.g., a gate, a back gate, or both) connected to receive a configuration signal(s) CFG.

Preferably, a deep channel JFET included within switch device 402-0 can be a depletion mode device. Thus, when signal(s) CFG is inactive, a channel of the deep channel JFET is not pinched off, and a switch device 402-0 can provide a low impedance path, preferably a path having a lower impedance than that achievable by shallow channel transistors of the same integrated circuit device. However, when signal(s) CFG is active, a channel of a deep channel JFET can be pinched off, thus providing a high impedance path.

Referring now to FIG. 5, a switch structure according to another embodiment is shown in a block schematic diagram and designated by the general reference character 500. A switch structure 500 can include some of the same general sections as those shown in FIG. 4, but can provide a greater degree of freedom in signal path configuration.

Unlike FIG. 4, switch structure 500 can include a second switch device 502-1, which can also include a deep channel JFET according to any of the above described embodiments or equivalents. Switch device 502 can enable or disable a signal path between a first signal line 506 and a third signal line 508. Switch devices 502-0 and 502-1 can be controlled according to signals CFG′.

Referring to FIG. 6, yet another switch structure according to an embodiment is shown in a block schematic diagram, and designated by the general reference character 600. A switch structure 600 can include some of the same general sections as that shown in FIG. 5, but can provide an even greater degree of freedom in signal path configuration, allowing any of signal points 610-0 to 610-3 to be connected to, or isolated from, one another.

In the arrangement of FIG. 6, a switch structure 600 can include a switch device 602-0 providing a controllable impedance path between signal point 610-0 and 610-1, a switch device 602-1 providing a controllable impedance path between signal point 610-0 and 610-2, a switch device 602-2 providing a controllable impedance path between signal point 610-0 and 610-3, a switch device 602-3 providing a controllable impedance path between signal point 610-1 and 610-2, a switch device 602-4 providing a controllable impedance path between signal point 610-2 and 610-3, and a switch device 602-5 providing a controllable impedance path between signal point 610-1 and 610-3. The conductivity of switch devices (602-0 to 602-5) can be controlled according to signals CFG″.

Any or all of switch devices 602-0 to 602-5 can include a deep channel JFET according to any of the above described embodiments or equivalents. Thus, for those switch devices including such a deep channel JFET, a signal(s) provided to the control terminal can pinch off the device when active.

In this way, switch circuits can include deep channel JFETs for providing configurable interconnections between two or more signal lines or signal points.

Having described switch structures that can include deep channel JFETs, circuits providing for the programmable configuration for such circuits will now be described.

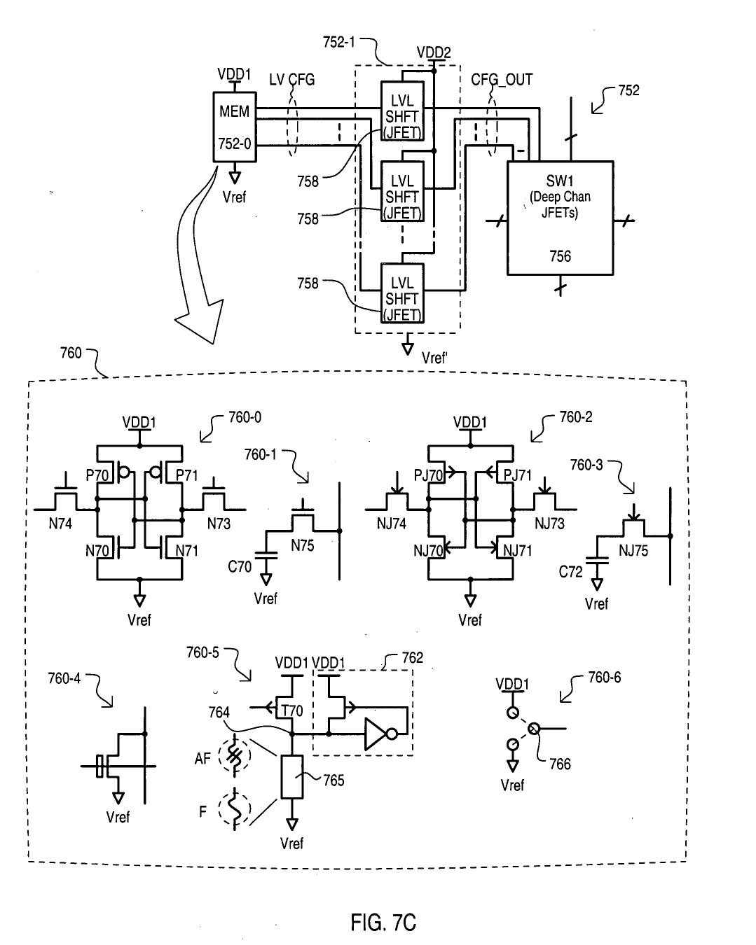

Referring now to FIG. 7A, a programmable switch circuit is shown in a block schematic diagram, and designated by the general reference character 700. A programmable switch circuit 700 can include a programmable switch section 702 and a low voltage section 704. A low voltage section 704 can operate at a predetermined supply voltage range, shown in FIG. 7A as VDD1 to Vref. As but one particular example, a voltage VDD1 can be a high power supply voltage and a voltage Vref can be ground. In particular embodiments, a low voltage section 704 can include shallow channel transistors like those shown in any of FIGS. 2A to 2C.

A programmable switch section 702 can include a switch structure 706 and a configuration circuit 708. A switch structure 706 can include one or more deep channel JFETs according to any of the above embodiments or equivalents. Further, any such deep channel JFET can be a depletion mode device, with voltages VDD1 and/or Vref being insufficient to place such a device into a low conductivity pinched off state. In particular arrangements, a switch structure 706 can include any of those shown in FIGS. 4 to 6.

Configuration circuit 708 can be programmed to provide output configuration signals CFG_OUT. Such programming can be based on nonvolatile or volatile storage circuits. Output configuration signals (CFG_OUT) can vary between Vref and a voltage VDD2. A voltage swing between VDD2 and Vref can be greater than that of VDD1 to Vref. In addition, output configuration signals (CFG_OUT) can be of sufficient magnitude to place any deep channel JFETs within switch structure 706 into the low conductivity pinch off state.

In one particular arrangement, a voltage VDD1 can be a first high power supply voltage, VDD2 can be a second high power supply voltage higher than VDD1, with Vref and Vref being ground. Deep channel JFETs within switch structure 706 can be p-channel JFETs placed into pinch-off by application of VDD2 to their gates.

In an alternate arrangement, a voltage VDD1 can be a first low power supply voltage (e.g., ground), VDD2 can be a second low power supply voltage lower than VDD1 (e.g., a negative supply voltage VBB), and Vref and Vref can be a high power supply voltage. Deep channel JFETs within switch structure 706 can be n-channel JFETs placed into pinch-off by application of VDD2 to their gates.

In yet another arrangement, a voltage VDD1 can be a first high power supply voltage, VDD2 can be a second high power supply voltage greater than VDD1. Voltage Vref can be a first low power supply voltage (e.g., ground) and Vref can be a second low power supply voltage lower than Vref (e.g., a negative supply voltage VBB). Deep channel JFETs within switch structure 706 can be both n-channel JFETs and p-channel JFETs, placed into pinch-off by application of Vref and VDD2 to their gates, respectively.

Referring now to FIG. 7B, a programmable switch section, like that shown as 702 in FIG. 7A, is shown in a block schematic diagram, and designated by the general reference character 732. A programmable switch section 732 can include configuration value circuit 732-0, a gate circuit 732-1, and a switch structure 736. A configuration value circuit 732-0 can output signals CFG_IN according to user or other application programming data.

A gate circuit 732-1 can operate between voltages VDD2 and Vref. As in the case of FIG. 7A, either or both of voltages VDD2 and/or Vref can be outside the range of a low voltage supply provided to other portions of an integrated circuit (e.g., VDD1 to Vref). A gate circuit 732-1 can receive values CFG_IN, and in response thereto provide signals CFG_OUT, which can vary between VDD2 and Vref, to switch structure 736.

Switch structure 736 can include any of the structures, or equivalents, as switch structure 706, described in conjunction with FIG. 7A.

Referring now to FIG. 7C, another programmable switch section, like that shown in FIG. 7A, is set forth in a block schematic diagram, and designated by the general reference character 752. A programmable switch section 752 can include a memory section 752-0, a level shift section 752-1, and a switch structure 756. A memory section 752-0 can operate between supply voltage VDD1 and Vref. In response to stored data values, memory section 752-0 can output low voltage configuration signals LV_CFG.

A level shift section 752-1 can operate between supply voltages VDD2 and Vref. Either or both of voltages VDD2 and/or Vref′ can be outside of the range provided by power supply voltages VDD1 and Vref. A level shift section 752-1 can include a level shift circuit 758 corresponding to each of signals LV_CFG. Each level shift circuit 758 can receive one of signals LV_CFG, which can vary between VDD1 and Vref, and shift it to vary between VDD2 and Vref′. Such shifted signals can then be provided as signals CFG_OUT to switch structure 756.

Switch structure 756 can include any of the structures, or equivalents, as switch structure 706, described in conjunction with FIG. 7A.

FIG. 7C shows various possible examples of memory cells 760 that can be included in memory section 752-0 for storing data values utilized to generate signals LV_CFG. It is understood that any of the memory cells shown in group 760 could be included and repeated as necessary to provide the number of signals LV_CFG needed to control switch structure 756.

Potential memory cells 760 of a memory section 752-0 include a “MOS” type static random access memory (SRAM) cell 760-0 that includes a latch formed by cross-coupled inverters (P70/N70 and P71/N71) and passgate transistors N73/N74, or a MOS type dynamic RAM (DRAM) cell 760-1, that can include a passgate transistor N75 and a storage capacitor C70. Inclusion of memory cells like 760-0 and/or 760-1 into a memory section 752-0, can allow such memory section to be manufactured with existing conventional MOS type techniques, allowing a programmable switch section according to the above embodiments to be easily incorporate into existing MOS type architectures.

In addition or alternatively, a memory cell can be a SRAM or DRAM type cells, but formed with JFET devices, as shown by memory cells 760-2 and 760-3. Preferably, such JFET devices can be shallow channel enhancement mode devices. Inclusion of memory cells like 760-2 and/or 760-3 into a memory section 752-0, can allow such memory section to be manufactured with advantageously low operating power supply (e.g., less than 0.7 volts, preferably less than about 0.5 volts). This can allow for an advantageously low power device.

It is noted that while memory cells 760-0 and 760-2 show SRAM cells having six-transistor (6-T) cell configurations, other embodiments can include different arrangements. As but one example, other SRAM memory cells can include four transistor (4-T) cells, in which transistors of the same conductivity type within a latch can be replaced by passive impedance elements, such as resistors, or “diode” connected transistors, or the like.

While memory cells of a memory section 752-0 can include volatile memory cells, other arrangements can include nonvolatile storage circuits. Two of many possible examples are also shown in FIG. 7C. Memory cell 760-4 shows one example of an electrically erasable read only memory cell (EEPROM), such as a “flash” type EEPROM cell that can be used to store configuration information. Inclusion of EEPROM type cells can enable configuration data for establishing the states of switch devices to be stored in a nonvolatile fashion.

Memory cell 760-5 shows another memory cell that includes a fuse-type device 764. In the particular example shown, a fuse type device 765 can be a fuse structure (F) or an anti-fuse structure (AF). A fuse structure (F) can be manufactured with a low impedance and programmed to provide a high impedance. Conversely, an anti-fuse structure (AF) can be manufactured with a high impedance and programmed to provide a low impedance. In the very particular example shown, memory cell 760-5 can include a preset transistor T70 and a half latch 762. Upon a state establishing condition (e.g., power-up or reset), preset transistor T70 can be activated to provide a low impedance, thus pulling a data node 764 to a high supply potential VDD1. If fuse-type device 765 is in a high impedance state, data node 764 can remain high and be latched in such a state by half-latch 762. Conversely, if fuse-type device 765 is in a low impedance state, data node 764 can be drawn toward a low supply potential Vref and half-latch 762 can be disabled. Of course, memory cell 760-5 represents but one of many possible memory cells based on fuse or anti-fuse structures, and should not be construed as limiting to the invention.

A memory cell 760-6 illustrates an arrangement that can include a mask option to establish a memory cell 760-6 output value. A memory cell 760-6 can include a node 766 that can be connected to one power supply level or the other (e.g., VDD1 or Vref) according to a pattern present in a manufacturing mask.

Inclusion of fuse-type structures or mask options can provide advantageously low power consumption for a resulting memory section, as little or no current is drawn by the state establishing devices.

Deep channel JFET devices, like those described above and equivalents, can be advantageously included in various architectures to increase performance of an IC. Various examples of such arrangements will now be described.

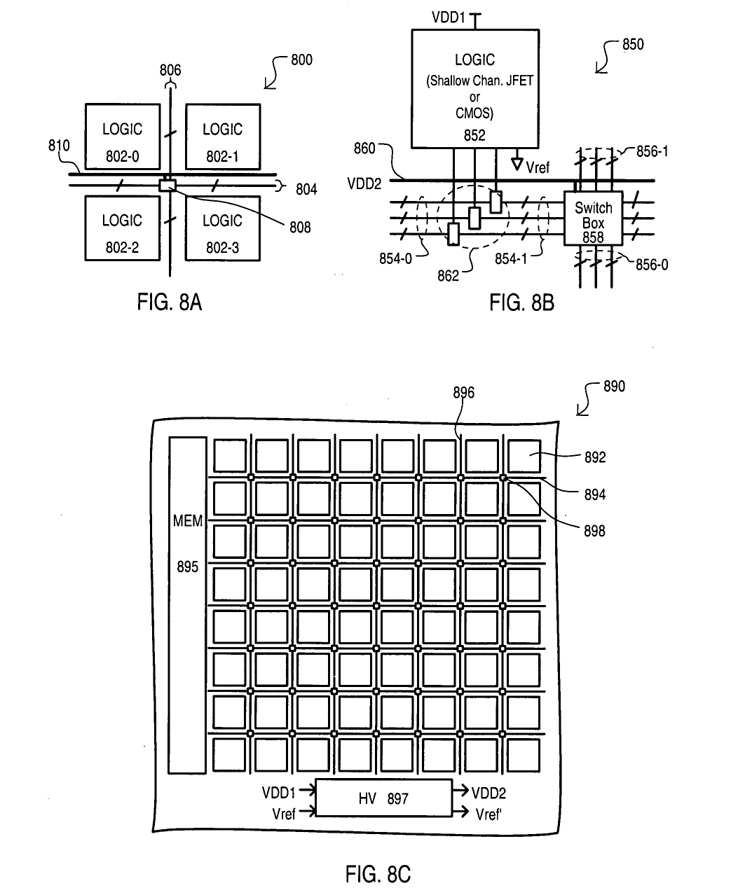

Referring now to FIG. 8A, a portion of a programmable logic device (PLD) architecture is shown in a block schematic diagram and designated by the general reference character 800. A PLD portion 800 can include a number of logic blocks 802-0 to 802-3, first signal line sets 804, second signal line sets 806, a switch box circuit 808, and configuration data lines 810. Logic blocks (802-0 to 802-3) can be connected to at least first signal line set 804 and can provide predetermined logic functions. Preferably, each logic block (802-0 to 802-3) is reconfigurable, providing a logic function that varies according to configuration data. Further, connections to/from a logic block (802-0 to 802-3) and signal line set (e.g., 804 and/or 806) can also configurable according to configuration data.

A switch box circuit 808 can be situated at the intersection of first signal line sets 804 and second signal line sets 806, and can include deep channel JFETs according to any of the above embodiments or equivalents. Even more particularly, intersections of such signal lines can include any of the switch structures shown in FIGS. 4 to 7B, or portions thereof. A switch box circuit 808 can enable signal propagation paths in a horizontal and/or vertical direction based on switch configuration data provided on configuration data lines 810.

Referring now to FIG. 8B, smaller portion of a PLD is shown in a block schematic diagram, and designated by the general reference character 850. A PLD portion 850 shows can include logic block 852, first signal line sets 854-0 and 854-1, second signal line sets 856-0 and 856-1, a switch box circuit 858, and configuration data lines 860. Logic block 852 can provide predetermined logic functions, preferably functions that vary according to configuration data. Inputs and/or outputs of logic block 852 can be connected to first signal line sets (854-0 and 854-1) by connection circuit 862. A logic block 852 can operate between a high power supply voltage VDD1 and a reference voltage Vref.

A switch box circuit 858 can selectively connect a line from any of signal line sets 856-0 to 856-3 to a corresponding line of another signal line set. In one arrangement, configuration data lines 860 can provide signals that vary between VDD1 and Vref, and switch box circuit 858 can operate between a high power supply voltage VDD2 and a reference voltage Vref′, where one or both such values are outside of the range VDD1 to Vref. Alternatively, configuration data lines 860 can transmit signals that vary between VDD2 and Vref′. Signal levels VDD2 and/or Vref can be of sufficient magnitude to place deep channel JFETs within switch box circuit 858 into pinch-off.

Referring now to FIG. 8C, a field programmable gate array (FPGA) according to an embodiment is shown in a block schematic diagram, and designated by the general reference character 890. An FPGA 890 can include a number of logic blocks (one shown as 892) interconnected to one another by a configurable signal wiring. A configurable signal wiring can include wiring sets, each having multiple wiring lines, arranged in vertical channels (one shown as 894) and wiring sets arranged in horizontal channels (one shown as 896). Wiring lines of one wiring set can be isolated from, or conductively connected to, a wiring in an adjacent wiring set (vertical and/or horizontal) by a switch box circuit (one shown as 898) arranged between such wiring lines. Each switch box circuit 898 can include any of the components or structures shown in FIGS. 4 to 8B, or equivalents.

In the particular example of FIG. 8C, an FPGA 890 can further include a memory circuit 895 and a high voltage supply circuit 897. A memory circuit 895 can store configuration data. Such configuration data can establish the states of switch box circuits, and in some embodiments, states of logic blocks. A memory circuit 895 can be based on any of the memory cells shows in FIG. 7C, and preferably is SRAM based.

A high voltage supply circuit 897 can generate supply voltage levels needed to place deep channel JFET switch devices into high impedance pinch off state. As but a few examples, a high voltage supply circuit 897 can include positive charge pump circuit to generate VDD2 in the event VDD2>VDD1. Similarly, a high voltage supply circuit 897 can include negative charge pump circuit to generate Vref in the event Vref>Vref′.

In this way, a programmable logic integrated circuit device can include deep channel JFETs for providing low resistance signal switching paths.

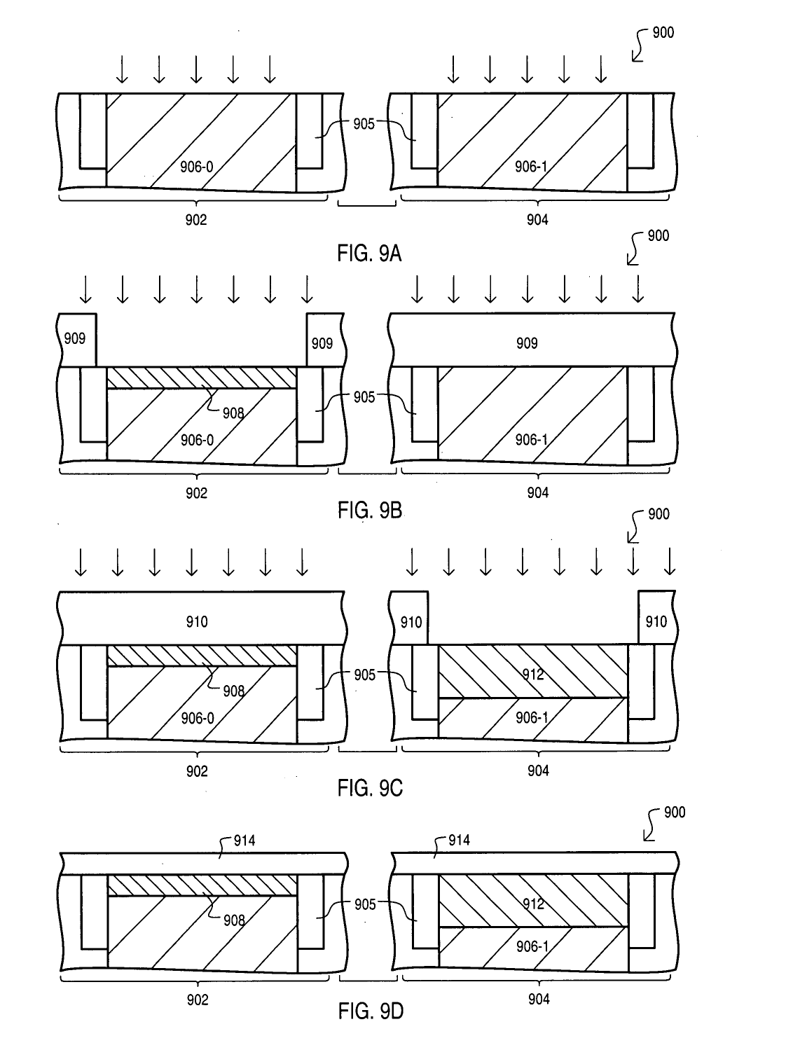

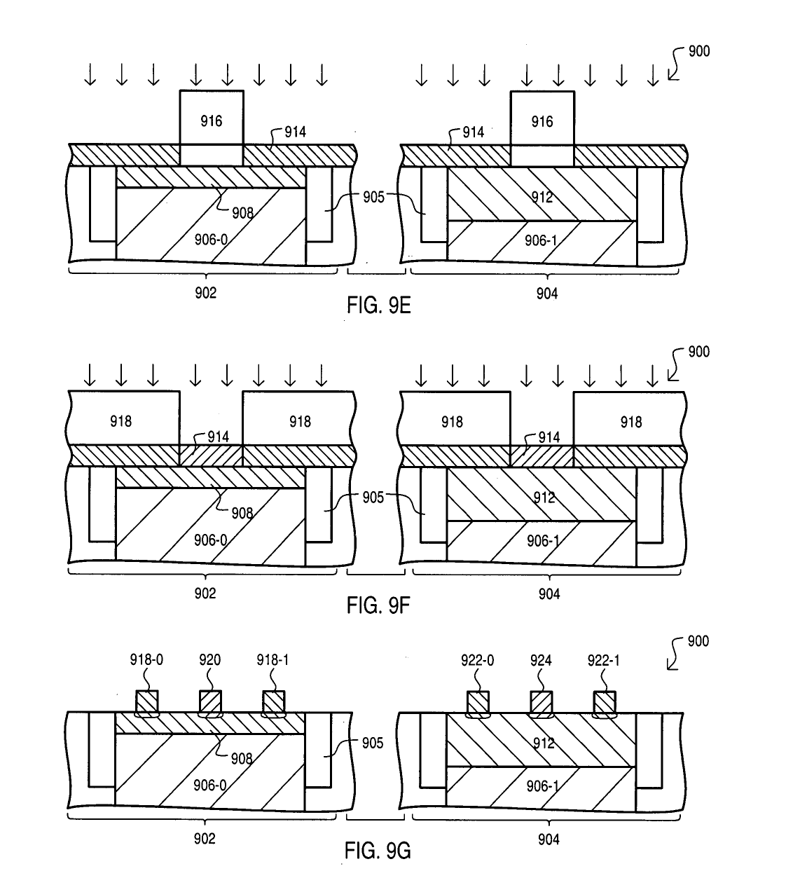

Referring now to FIGS. 9A to 9G, a method of forming a deep channel JFET (like that shown in FIGS. 3A-0 and 3A-1) with a shallow channel JFET (like that shown in FIG. 2A), is illustrated in a series of side cross sectional views. FIGS. 9A to 9G show the formation of deep and shallow channel JFETs of the same conductivity type, however, alternate arrangements can form different conductivity type devices using doping of opposite conductivity type.

Referring now to FIG. 9A, an integrated circuit device 900 can include a substrate having a first portion 902 and a second portion 904. Isolation structures 905 can be formed within first and second portions (902 and 904) to create active areas for the formation of both deep and shallow channel JFET devices. In one very particular arrangement, isolation structures can be formed with shallow trench isolation (STI) techniques. Optionally, a first and second portions (902 and 904) can be subject to a JFET well (or back gate) formation step, such as an ion implantation step. In FIGS. 9A to 9J, JFETs will be p-channel JFETs. Accordingly, a well formation step can create a first n-type well 906-0 in first portion 902, and a second n-type well 906-1 in a second portion 904.

Referring now to FIG. 9B, a first portion 902 can be subject to a JFET shallow channel formation step, such as another ion implantation step. A deep channel mask 909 can be created utilizing lithographic techniques that provide an opening at locations where a shallow channel JFET is to be formed. A channel impurity can be opposite to that of a well impurity, and thus can create a p-type channel 908. Such a p-type channel 908 will be considered “shallow” with respect to that of a “deep” channel JFET. At the same, time a second portion 904, in which a deep channel JFET is to be formed, can be masked with deep channel mask 909.

In alternate embodiments, deep channel JFETs can be included in the same channel formation steps as shallow channel JFETs. In such arrangements, a deep channel mask 909 would not be utilized.

Referring now to FIG. 9C, a second portion 904 of a substrate can be subject to a JFET deep channel formation step, such as another ion implantation step. A shallow channel mask 910 can be created utilizing lithographic techniques that provide openings at locations where a deep channel JFET is to be formed. A channel impurity can be opposite to that of a well impurity, and thus can create a p-type deep channel 912, that can be considered a deep channel as compared to channel 908. Preferably, a step like that shown in FIG. 9C can include one or more ion implantation steps at a greater energy than that used to form channel 908, but at a lower dose. In this way, a deep channel 912 can preferably extend deeper into a substrate than shallow channel 908, but have a lower concentration of p-type dopants of a shallow channel 908.

Referring now to FIG. 9D, a semiconductor electrode material 914 can be formed over first and second portions (902 and 904). An electrode material 914 can be a material capable of forming a pn junction with a channel region. In one particular example, an electrode material 914 can be silicon, preferably polycrystalline silicon (polysilicon), formed over and in contact with a silicon substrate including portions 902 and 904.

Referring now to FIGS. 9E and 9F, first and second portions (902 and 904) can be subject to electrode doping steps. Such steps can dope portions of a semiconductor material 914 to a particular conductivity type and concentration to form certain electrodes of a both a shallow channel and deep channel JFET.

Referring to FIG. 9E, an electrode material 914 can be doped to form source and drain electrodes for both shallow and deep channel JFETs. Accordingly, a gate mask 916 can be formed over portions of an electrode material 914 from which a gate electrode is to be formed. Areas exposed by gate mask 916 can be subject to a p-type implantation step, to form source and drain electrodes having the same conductivity type as their respective channel regions 908 and 912.

Referring to FIG. 9F, an electrode material can be doped to form gate electrodes for both shallow and deep channel JFETs. Accordingly, a source/drain mask 918 can be formed over portions of electrode material 914 from which a source or drain electrodes are to be formed. Areas exposed by gate mask 916 can be subject to an n-type implantation step to form gate electrodes having the opposite conductivity type as their respective channel regions 908 and 912.

Referring now to FIG. 9G, first and second portions (902 and 904) can be subject to an electrode patterning step. Such a step can include etching doped electrode material 914 into electrode structures. Such as step can be reactive ion etch, as but one example. In addition, a more conductive layer could be formed over semiconductor material 914, such a silicide layer. This more conductive layer can be formed prior to, or after electrodes are patterned. Subsequently, an integrated circuit device 900 can be subject to heat treatment step that can cause impurities to out diffuse from electrodes into a substrate below. Resulting electrodes can include a first shallow channel source/drain electrode 918-0, a second shallow channel source/drain electrode 918-1, a shallow channel gate electrode 920, as well as a first deep channel source/drain electrode 922-0, a second deep channel source/drain electrode 922-1, and a deep channel gate electrode 924.

In this way, both deep and shallow channel JFETs can be formed in the same substrate. Further, electrodes for such devices can be formed with a same semiconductor layer.

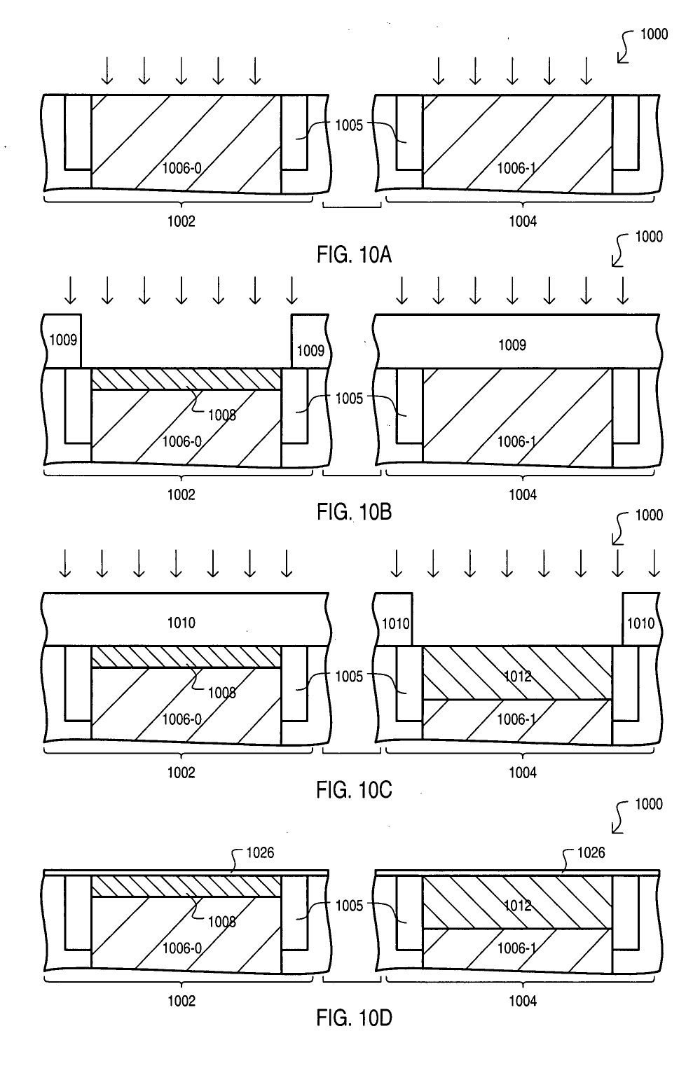

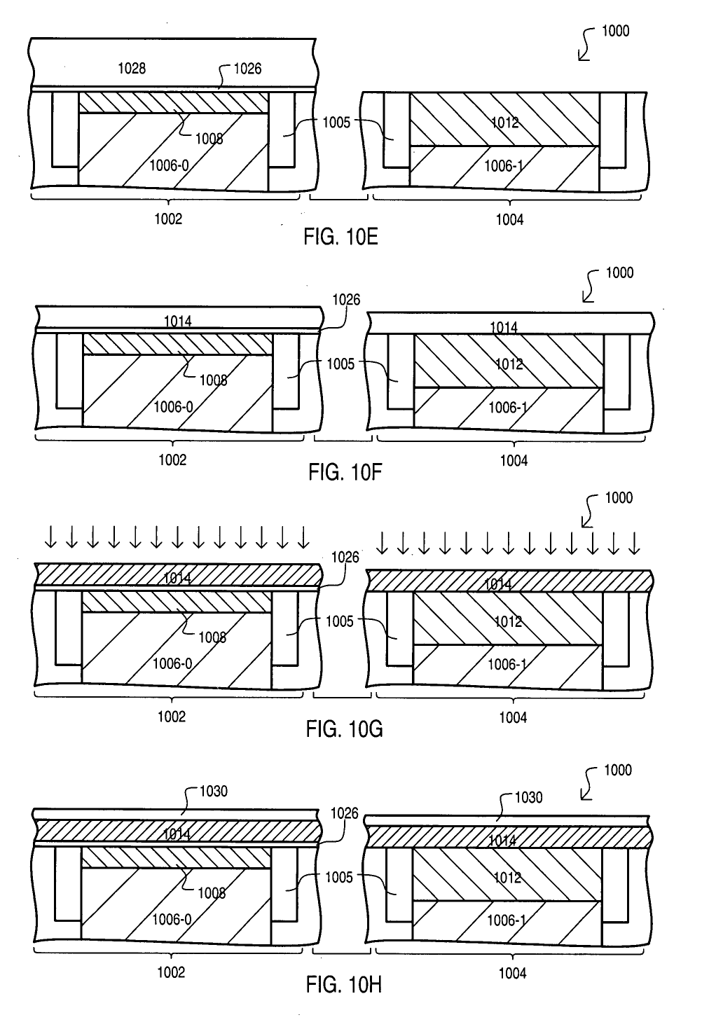

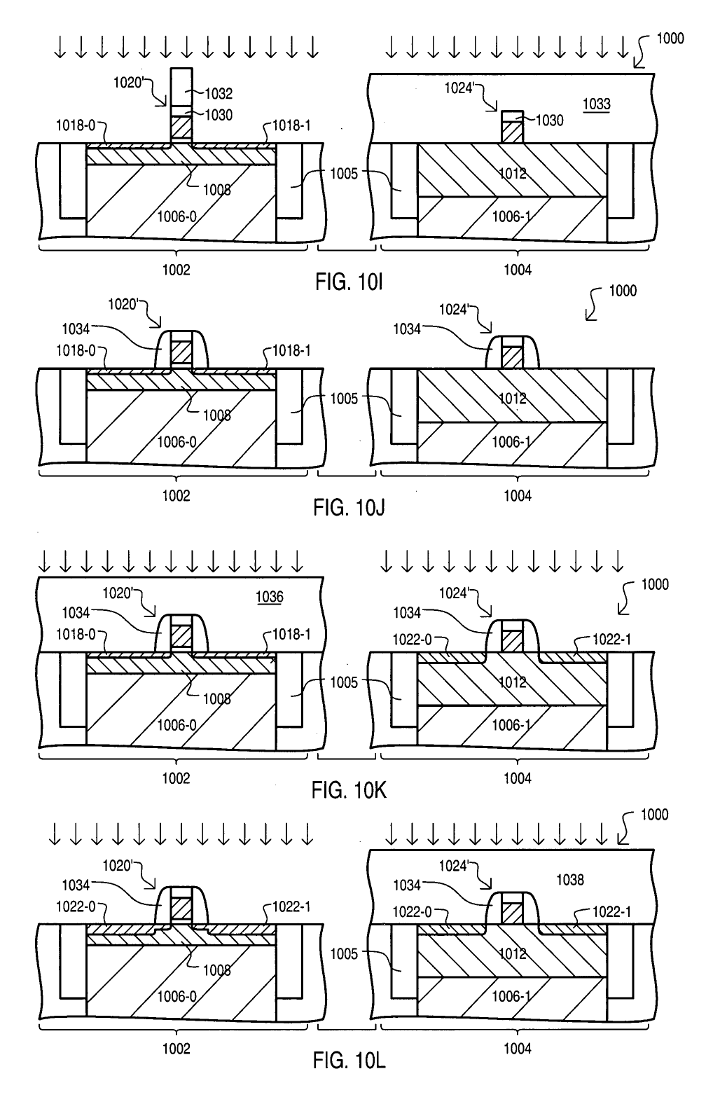

Referring now to FIGS. 10A to 10L, a method of forming a deep channel JFET (like that shown in FIG. 3B) with a shallow channel IGFET (like that shown in FIG. 2B), is illustrated in a series of side cross sectional views. FIGS. 10A to 10L show the formation of a deep JFET having a channel conductivity type opposite to that of the corresponding shallow channel IGFET. However, alternate arrangements can form different conductivity type devices using doping of opposite conductivity type.

FIGS. 10A to 10C show the same general steps as those shown in FIGS. 9A to 9C. Accordingly, like items are referred to by the same reference character but with the first digit being a “10” instead of a “9”.

Referring now to FIG. 10D, unlike the arrangement of FIG. 9A to 9G, a method can include forming a gate insulator layer over a surface of a substrate, in particular over first portion 1002. In the very particular example of FIG. 10D, a gate insulator 1026 can be formed over first and second portions (1002 and 1004), preferably with an oxidation step that oxidizes a substrate surface to form a gate oxide insulator.

Referring to FIG. 10E, a gate mask 1028 can be formed that masks regions where IGFET devices are to be formed, and exposes regions where deep channel JFETs are to be formed. An integrated circuit device 1000 can then be subject to a gate insulator removal step that can remove gate insulator 1026 over channel regions where deep channel JFETs are to be formed.

Referring now to FIG. 10F, a semiconductor electrode material 1014 can be formed over first and second portions (1002 and 1004). An electrode material 1014 can be a material suitable for creating an IGFET gate electrode, and also capable of forming a pn junction with a channel region. Accordingly, in particular examples, a semiconductor material 1014 can be silicon, preferably polycrystalline silicon (polysilicon), formed over gate insulator 1026 in first portion 1002, and over and in contact with a silicon substrate in second portion 1004.

Referring to FIG. 10G, an electrode material can be doped to form gate electrodes for both shallow channel IGFETs and a deep channel JFETs. An electrode material can subject to an ion implantation step with dopants of an opposite conductivity type to channel region 1012. Thus, in the example of FIG. 10G, electrode material 1014 can be subject to an n-type implantation step. In particular embodiments, a method can further include forming a more conductive layer on top of, and in ohmic contact with electrode material 1014. As but one example, a layer of silicide can be formed on electrode material 1014.

Referring to FIG. 10H, a top gate insulator 1030 can be formed over gate electrode material 1014. In particular embodiments, such a top gate insulator 1030 can include a layer of silicon dioxide, silicon nitride, silicon oxynitride or some combination thereof.

Referring to FIG. 101, a gate electrode etch mask 1032 can be formed on top gate insulator 1030 in a pattern corresponding to a desired gate electrode shape. A semiconductor device 1000 can then be subject to one or more etch steps that remove layers not covered by gate electrode mask 1032. As a result, an IGFET gate electrode 1020′ can be formed in first portion 1002, and a deep channel JFET gate electrode 1024′ can be formed in second portion 1004. A gate electrode mask 1032 can then be removed. In one particular arrangement, a semiconductor device 1000 can then be subject to an IGFET source/drain formation step that can form source/drain regions (1018-0 and 1018-1) in channel region 1008 having a conductivity type opposite to that of channel region 1008. Regions containing a deep channel JFET can be masked from such a step with a JFET mask 1033. In one particular arrangement, such a step can include an ion implantation step.

Referring to FIG. 10J, sidewall insulators 1034 can be formed on sides of gate electrodes (1020′ and 1024′). As but one example, an insulating layer can be formed over such gate electrodes and then subject to an anisotropic etch step.

Referring now to FIG. 10K, an IGFET mask 1036 can be formed over regions where IGFET devices are to be formed. Regions where a deep channel JFET is to be formed can be exposed. A semiconductor device 1000 can then be subject to a JFET source/drain formation step that can form source/drain regions (1022-0 and 1022-1) in channel region 1012 having a conductivity type that is the same as that of channel region 1012. In one particular arrangement, such a step can include an ion implantation step.

Referring to FIG. 10L, optionally, a semiconductor device 1000 can be subject to a second IGFET source/drain formation step. Regions where a JFET is to be formed can be masked, while regions where an IGFET is to be formed can be exposed. A semiconductor device 1000 can then be subject to a second JFET source/drain formation step that can form source/drain regions (1022-0 and 1022-1) in channel region 1008 having a conductivity type opposite to that of channel region 1008. In one particular arrangement, such a step can include an ion implantation step having a greater energy than that of FIG. 101.

In this way, deep channel JFETs and shallow channel IGFETs can be formed in the same substrate. Further, electrodes for such devices can be formed with some of the same process steps.

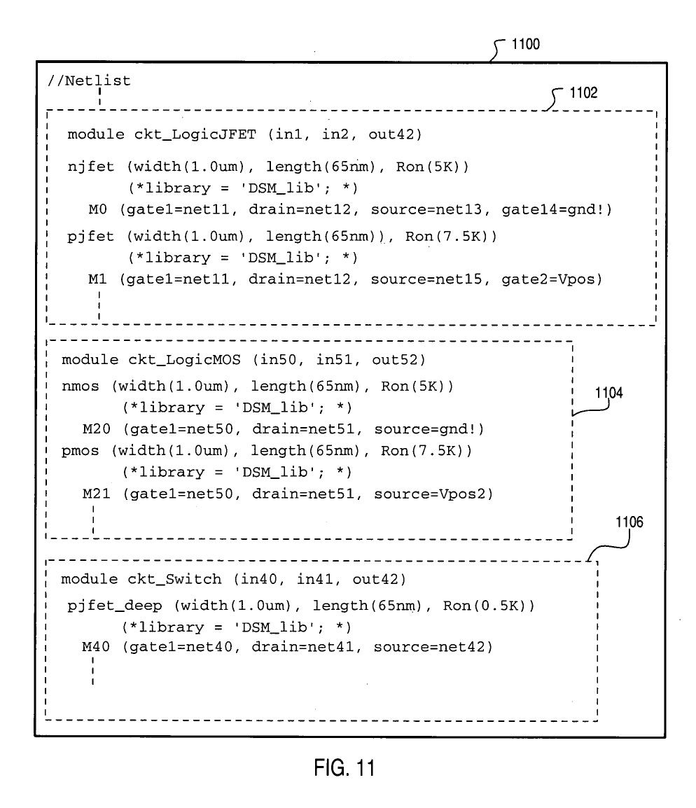

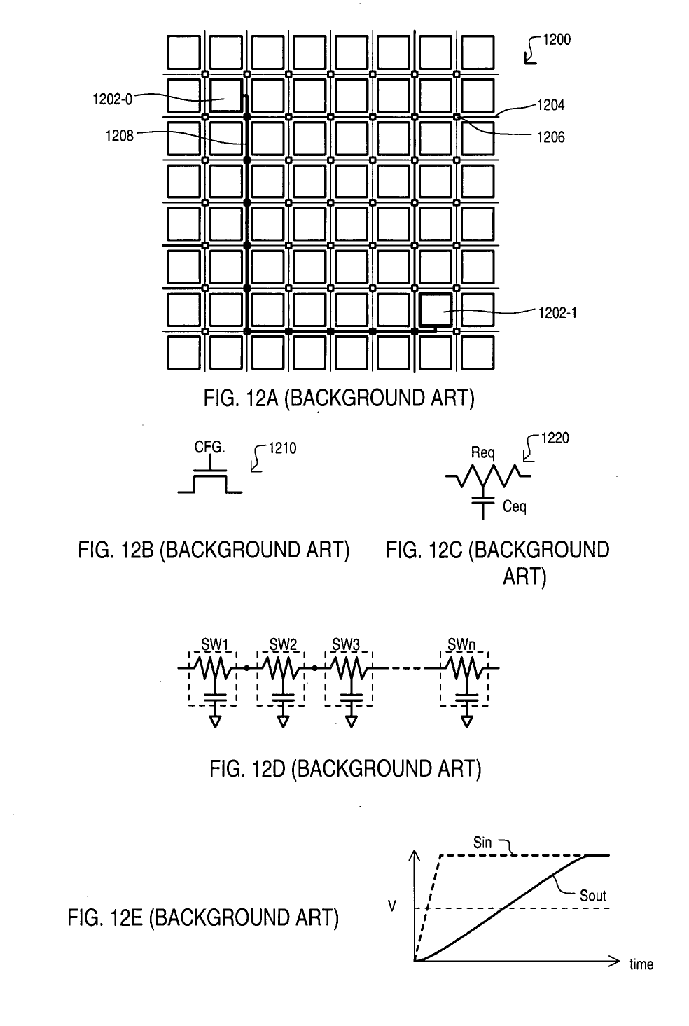

Referring now to FIG. 11, a design according to one particular embodiment is shown as a netlist in text form and designated by the general reference character 1100. A design 1100 can include declarations of element types and associated interconnections arranged into modules.

In the particular example shown, a design 1100 can include a JFET logic module “ckt_LogicJFET” 1102 and switch module “ckt_Switch” 1106. Optionally, a design 1100 can include an IGFET logic module “ckt_LogicMOS” 1104. A JFET logic module 1102 can include JFET devices interconnected to one another, and can include devices with a given “on” resistance of 5K ohms. An “on” resistance can exist upon application of a gate voltage (i.e., the device is an enhancement mode device). In one particular arrangement, models “njfet” and “pjfet” can be based on structures like those shown in FIG. 2A or 2C, or equivalents.

A switch module “ckt_Switch” 1106 can include a p-type deep channel JFET device (pjfet_deep) that can interconnect one node (net41) to another (net42). Such a device can have an “on” resistance substantially less than that of other devices (0.5K ohms). An “on” resistance can exist absent the application of a gate voltage (i.e., the device is a depletion mode device). Such a deep channel device can be modeled on any of the structures shown in FIGS. 3A-0 to 3D. Of course, a design can include an n-type deep channel device as well.

From the above it is understood that for a given transistor size (i.e., W/L=1 μm/65 nm) a transistor can have a resistance parameter “Ron”. It is noted that for such same size unit W=1 μm, a deep channel JFET has a lower resistance value Ron than either the shallow channel JFETs or MOSFETs.

The particular example of FIG. 11 also includes the incorporation of IGFET (e.g., MOS) type transistors into the same integrated circuit. Consequently, the design 1100 can include IGFET logic module “ckt_LogicMOS” 1104. An IGFET driver module 1104 can include IGFET devices interconnected to one another. Such IGFET devices can include an “on” resistance (5K ohms) larger than that of deep channel devices of module ckt_Switch. An “on” resistance can exist upon application of a gate voltage that places a corresponding channel into inversion (i.e., the device is an enhancement mode device).

In this way, a design can include switch modules that can provide low resistance switching paths for signals of an integrated circuit design.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is, an inventive feature of the invention may include an elimination of an element.

While various particular embodiments set forth herein have been described in detail, the present invention could be subject to various changes, substitutions, and alterations without departing from the spirit and scope of the invention.

What is claimed is:

1. An integrated circuit device, comprising:
a plurality of field effect transistors (FETs) having channel depths no greater than a first depth; and
at least a first switch junction FET (JFET) having a source coupled to a signal transmission input node, a drain coupled to a signal transmission output node, and a gate, the at least first switch JFET having a channel depth greater than the first depth.

2. The integrated circuit device of claim 1, wherein:
the plurality of field effect transistors comprise insulated gate field effect transistors.

3. The integrated circuit device of claim 1, wherein:
the plurality of field effect transistors comprise JFETs having source, drain, and gate electrodes formed from a semiconductor material deposited on a semiconductor substrate.

4. The integrated circuit device of claim 1, wherein:
the at least first switch JFET includes at least a gate electrode formed from a semiconductor material deposited on a semiconductor substrate.

5. The integrated circuit device of claim 4, wherein:
the at least first switch JFET includes at least a source/drain electrode formed from the semiconductor material deposited on the semiconductor substrate.

6. The integrated circuit device of claim 1, wherein:
the at least first switch JFET forms at least part of a switch element, the switch element including at least a first signal line coupled to the source of the at least first switch JFET and a second signal line coupled to the drain of the at least first switch JFET.

7. The integrated circuit device of claim 6, wherein:
the at least first switch JFET further includes a second switch JFET; and
the switch element further includes the first signal line coupled to a source of the second switch JFET and a third signal line coupled to a drain of the second switch JFET.

8. The integrated circuit device of claim 1, further including:
the plurality of FETs having channel depths no greater than a first depth are coupled to receive a power supply voltage having a first magnitude;
a high voltage configuration circuit that outputs at least a first configuration signal having a signal swing that is greater than the first magnitude; and
the at least a first switch JFET has a gate coupled to receive the at least first configuration signal.

9. The integrated circuit device of claim 8, wherein:
the high voltage configuration circuit includes
a storage circuit that includes at least some of the plurality of FETs having channel depths no greater than a first depth, and provides at least one stored output value having a value no greater than the first magnitude, and
at least one level shifting circuit that shifts the at least one stored output value to generate the at least first configuration signal.

10. The integrated circuit device of claim 1, wherein:
the first depth has a value d; and
the at least first switch JFET has a channel of depth X*d, where X is from about 1.5 to about 4.

11. The integrated circuit device of claim 1, further including:
the integrated circuit device comprises a programmable logic device;
the plurality of FETs having channel depths no greater than a first depth form a plurality of logic circuits interconnected to one another by programmable signal paths that include signal transmission lines connected to one another by switch circuits; and
the at least a first switch JFET is included in at least one of the switch circuits and has its source coupled to at least a first of the signal transmission lines and its drain coupled to at least a second of the signal transmission lines.

12. The integrated circuit device of claim 1, wherein:
the at least a first switch JFET has greater channel depth by a region of the channel in a channel width direction not being covered by a gate electrode.

13. A method of fabricating an integrated circuit device, comprising the steps of:
forming a first active area for at least one shallow channel field effect transistor (FET) having impurities extending into a first substrate region to a depth d;
forming a second active area for at least one deep channel junction FET (JFET) having impurities extending into a second substrate region to a depth greater than d; and
forming at least a gate terminal of the at least one deep channel JFET by patterning an electrode semiconductor material formed on, and in contact with, at least a portion of the second substrate region.

14. The method of claim 13, further including:
the at least one shallow channel FET is a shallow channel junction FET (JFET); and
forming at least one source/drain terminal and a gate terminal of the at least one shallow channel JFET by patterning the electrode semiconductor material formed on, and in contact with, at least a portion of the first substrate region.

15. The method of claim 14, wherein:
the first active area comprises a substrate semiconductor material doped to a conductivity type; and
the at least one source/drain terminal comprises the electrode semiconductor material doped to the same conductivity type as the substrate semiconductor material and the gate terminal comprises the electrode semiconductor material doped to a different conductivity type than the substrate semiconductor material of the first active area.

16. The method of claim 13, further including:
forming at least a gate terminal of the at least one deep channel JFET further includes forming at least one source/drain terminal by patterning the semiconductor material formed on, and in contact with, at least a portion of the second substrate region.

17. The method of claim 16, wherein:
the second active area comprises a substrate semiconductor material doped to a conductivity type; and
the gate terminal of the at least one deep channel JFET comprises the electrode semiconductor material doped to a different conductivity type than the substrate semiconductor material of the second active area.

18. The method of claim 13, wherein:
the at least one shallow channel field effect transistor (FET) is an insulated gate field effect transistor.

19. An integrated circuit design, comprising:
a plurality of logic circuit structures defined as operating within a first voltage range, each structure defined as including enhancement mode field effect transistors (FETs); and
at least one switching structure defined as connecting one signal node to another signal node, the at least one switching structure including at least one depletion mode junction FET (JFET), the at least one depletion mode JFET receiving a configuration signal at its gate having a swing greater than the first voltage range.

20. The integrated circuit design of claim 19, wherein:
the enhancement mode FETs are defined as having a shallow channel resistance parameter; and
the at least one depletion mode JFET has a deep channel resistance parameter, the deep channel resistance parameter being lower in value than the shallow channel resistance parameter.

21. The integrated circuit design of claim 20, wherein:
the enhancement mode FETs are selected from the group consisting of insulated gate FETs and junction FETs.

22. The integrated circuit design of claim 20, wherein:
the shallow channel resistance parameter corresponds to a channel size unit value; and
the deep channel resistance parameter corresponds to the same channel size unit value.

23. An integrated circuit device, comprising:
a plurality of logic blocks, each configurable to execute one of multiple logic functions, each logic block comprising a plurality of transistors; and
a plurality of switch circuits, each switch circuit having at least one switch path configurable to electrically interconnect at least one logic block with another logic block, each switch path comprising at least one depletion mode switch junction field effect transistor (JFET).

24. The integrated circuit device of claim 23, wherein:
the plurality of transistors comprise logic FETs, each logic FET including a channel area covered by gate electrode; and
each switch JFET includes a channel area covered by a gate electrode; wherein
a ratio of the channel area taken in a width direction to channel surface covered by the gate electrode in the width direction is greater for each switch JFET than any of the logic FETs.

25. The integrated circuit device of claim 23, wherein:
the plurality of transistors comprise logic FETs having channels that extend no more than a distance d below their corresponding gate electrode; and
at least one switch JFET has a channel that extends more than d below its corresponding gate electrode.

26. The integrated circuit of claim 23, wherein:
the integrated circuit comprises a programmable logic device.

27. The integrated circuit of claim 23, further including:
a first power supply node coupled to a receive a first power supply voltage having a first magnitude with respect to a reference voltage;
a second power supply node coupled to receive a second power supply voltage having a greater magnitude with respect to the reference voltage than the first power supply voltage;
a configuration circuit for selectively connecting gates of the switch JFETs to the second power supply node according to configuration data.

28. The integrated circuit of claim 29, further including:
a boosted power supply generator coupled to the first power supply node and a reference voltage that generates the second power supply voltage on the second power supply node.
